(19) United States
(12) Patent Application Publication
(10) Pub. No.: US 2011/0318497 A1
(43) Pub. Date: Dec. 29, 2011

(54) HOISTWAY SHEAVE RESURFACING

(75) Inventors: James T. Beals, West Hartford, CT (US); Mark Steven Thompson, Tolland, CT (US); Wayde R. Schmidt, Pomfret Center, CT (US); Aaron T. Nardi, East Granby, CT (US); Gregory S. Welsh, Vernon, CT (US)

(73) Assignee: OTIS ELEVATOR COMPANY, Farmington, CT (US)

(21) Appl. No.: 13/141,714

(22) PCT Filed: Dec. 23, 2008
(86) PCT No.: PCT/US08/13995

§ 371 Date: Jun. 23, 2011

(51) Int. Cl. B05D 3/00; C25D 7/00; C25D 5/02; B05D 1/08; C23C 14/28

(52) U.S. Cl. 427/446; 427/140; 427/580; 427/596; 427/444; 205/115; 205/122

(57) ABSTRACT

A method of and system for repairing the sheaves (24) in an elevator system has these steps. The ropes (22) associated with the sheave are removed, the sheave is cleaned, and a coating (24) is deposited on the cleaned surface. The coating is adapted to reduce the wear coefficient of the surface of the coated sheave by about 80% to 90% with respect to the sheave without a coating. The thickness of the coated sheave is adjusted to produce a specified sheave diameter.

### BACKGROUND

The invention relates to elevator systems and more particularly to elevator sheaves that are subjected to wear during use.

A conventional traction elevator system typically includes a car, a counterweight, two or more tension members (such as round ropes) interconnecting the car and counterweight, a traction sheave to move the ropes, and a machine to rotate the traction sheave. The machine may be either a geared or gearless machine. A geared machine permits the use of a higher speed motor, which is more compact and less costly, but requires additional maintenance and space.

The ropes (whether the ropes are for the car and counterweight or for the overspeed governor) can be formed from laid or twisted steel wire and the sheave (whether the drive sheave, deflector sheave or governor sheave) can be formed from cast iron. Differential tension on each side of the sheave, or rope deformation due to the tension applied, or misalignment of the sheave, can all cause relative motion between the rope and the sheave. The contact plus relative motion results in wear of the sheave and wire rope. Additionally, in the overspeed governor situation the sheave may be used for applying significant tension to the rope to actuate the safeties on the elevator. This function requires controlled friction between the sheave and the rope.

Large traction sheaves are often made from cast iron and can sometimes exhibit excessive wear in use. The sheaves function in combination with ropes that raise and lower elevator cars in various elevator systems such as those where the elevator car is supported by hoist ropes that are driven by a hoist motor. Elevator systems may also employ a counterweight at the opposite end of the hoist ropes. An example of an elevator system having a counterweight is described in commonly owned U.S. Pat. No. 3,610,342.

Conventional steel rope and cast iron sheaves have proven to be very reliable and cost effective. One limitation of these arrangements is the traction forces between the ropes and the sheaves. While ropes can be replaced, cast iron sheaves are difficult to maintain. One remedy is machining the sheaves in the hoistway, but this has limited effectiveness due to the confines of the hoistway space. Often times, full replacement of the sheave is required, which is expensive and results in unwanted down time. In some situations, full replacement of sheaves may require de-construction of the building and considerable down time for an elevator.

If larger sheaves are used, to obtain longer life or to accommodate additional ropes or a thicker cross section of a steel rope, more torque is required from the machine to drive the elevator system, thereby increasing the size and cost of the elevator system.

### SUMMARY

The present invention provides a method of repairing the sheaves in an elevator system.

The method includes selecting a sheave to be repaired, removing the at least one rope associated with the selected sheave, cleaning the sheave to restore the sheave to a desired condition, depositing a coating on the cleaned surface of the sheave, the coating being adapted to reduce the wear coefficient of the surface of the sheave. The coating provides a wear coefficient on the sheave of less than 2.0×10¹⁰ mm²N and more preferred are wear coefficients of less than 1.0×100 mm²N. This results in a reduction in wear coefficient of about 20% to 10% of the wear coefficient of the sheave without a coating (i.e., over 80% to 90% reduction). The thickness of the coated sheave may be adjusted to a predetermined level, such as original equipment dimension specifications for the sheave.

### BRIEF DESCRIPTION OF THE DRAWINGS

FIG. 1 is a perspective view of an elevator system having a traction drive and in a hoistway with the machine room in accordance with the present invention.

FIG. 2 is a sectional side view of the traction drive, showing a tension member and a sheave.

FIG. 3 is a perspective view of a drive in an elevator system illustrating a diverter or secondary sheave.

FIG. 4 is a perspective view of an elevator system illustrating the use of other sheaves.

### DETAILED DESCRIPTION

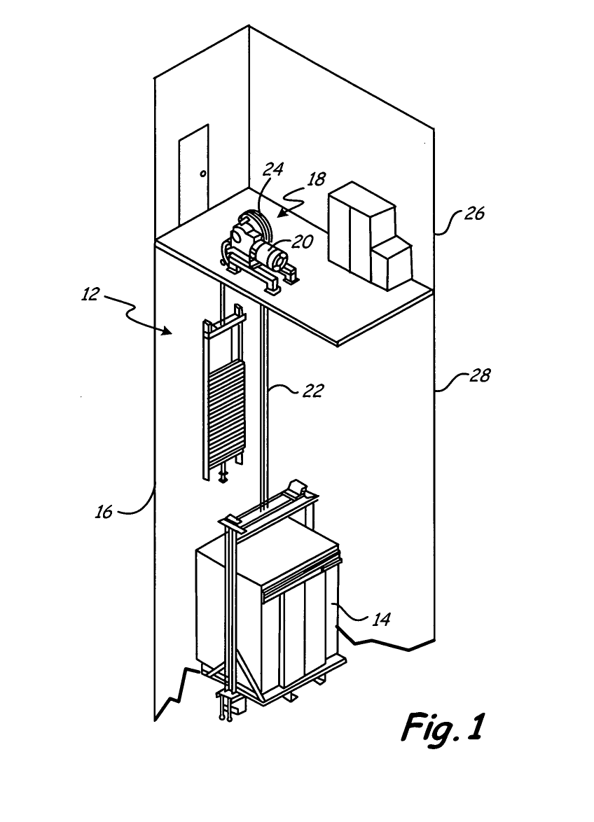

As shown in FIG. 1, a traction elevator system 12 includes a car 14, a counterweight 16, a traction drive 18, and a machine or motor drive unit 20. The traction drive 18 includes a tension member 22, interconnecting the car 14 and the counterweight 16, and a traction sheave 24. This system as shown is a 1:1 rope system. The invention does not depend on the specific rope system but functions to repair sheave surfaces in any rope system, such as 2:1 rope systems and any other elevator system where sheaves and ropes or other tension members are employed.

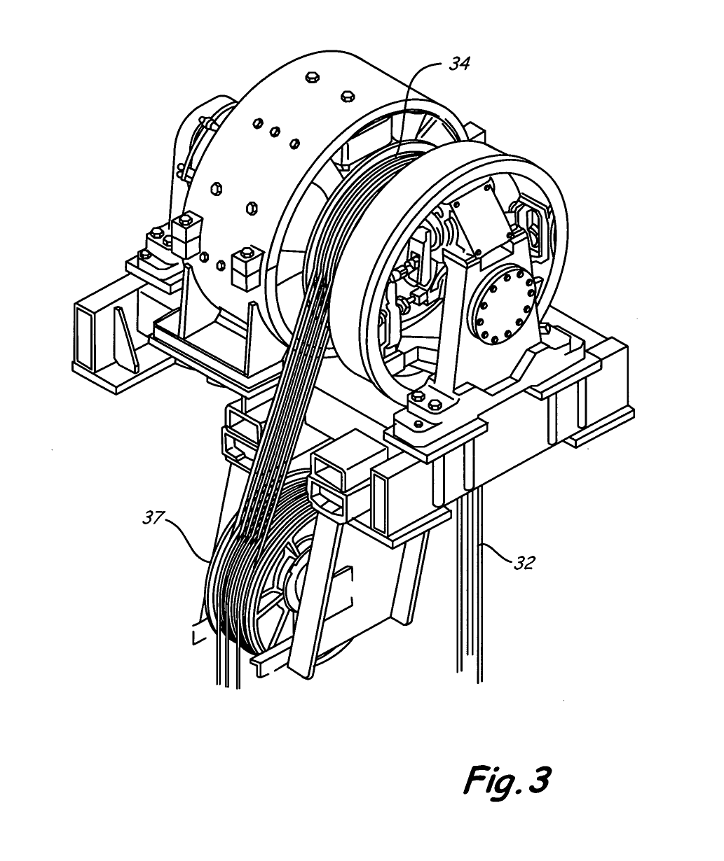

To achieve the desired arrangement of the ropes in the hoistway, the elevator system could include one or more deflector sheaves. The ropes engage the deflector sheave, but unlike the traction sheave do not drive the ropes. FIG. 3 illustrates deflector sheave 37 that functions to divert the path of tension member 32 that is driven by drive sheave 34.

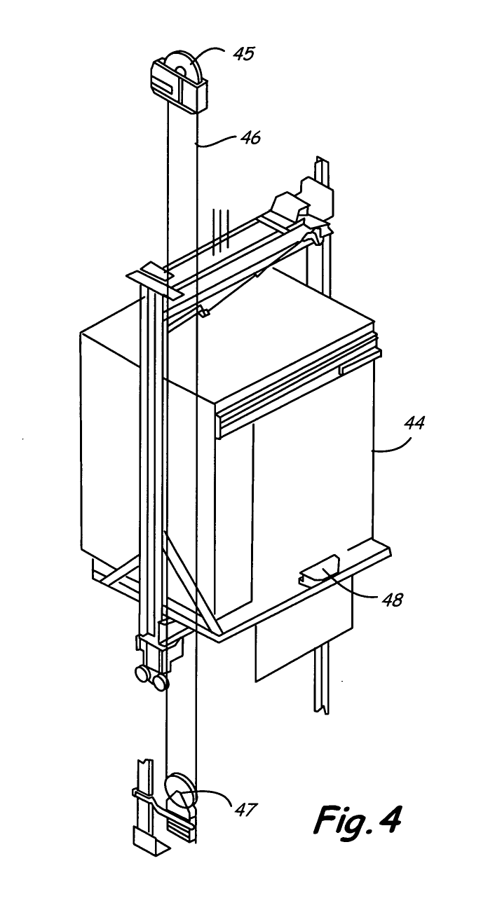

The elevator system can also include a safety system, as seen in FIG. 4, to ensure the car 44 does not exceed a predetermined limit. The safety system can include an overspeed governor and safeties. The overspeed governor includes a governor rope 46 extending the length of the hoistway, attached to a governor sheave 45 and a tensioner 47. If the speed of the car exceeds the predetermined limit, a centrifugal flyweight assembly driven by the governor sheave 45 would swing outwardly, tripping a switch thereby removing power to the elevator machine. If the speed of the car continues to increase, the flyweight assembly would swing outwardly still further and operate a governor brake. The governor brake would apply a frictional drag force to the governor rope 46, thereby actuating a pair of safety wedges 48 in communication with the governor rope 46. The safety wedges 48, attached to the elevator car 44, act on the elevator guide rails.

Since the sheaves can be used in a variety of shapes and sizes, depending on the specific use for which they are intended. Each has a predetermined shape and size for engagement with at least one rope or other friction element in the elevator system. It is to be understood that any sheave used in an elevator system for friction engagement with a friction element is within the scope of this invention.

As seen in FIG. 1, tension member 22 is engaged with the sheave 24 such that rotation of the sheave 24 moves the tension member 22, and thereby the car 14 and counterweight 16. The machine 20 is engaged with the sheave 24 to rotate the sheave 24. Although shown as a geared machine 20, it is noted that this configuration is for illustrative purposes only, and the present invention may be used with geared or gearless machines and with other elevator systems. All that is required is that there is a sheave and a friction element that engages the sheave. The elevator system 12 is located below the machine room 26 and inside hoistway 28, illustrating a typical but not limiting arrangement of the elevator inside a building.

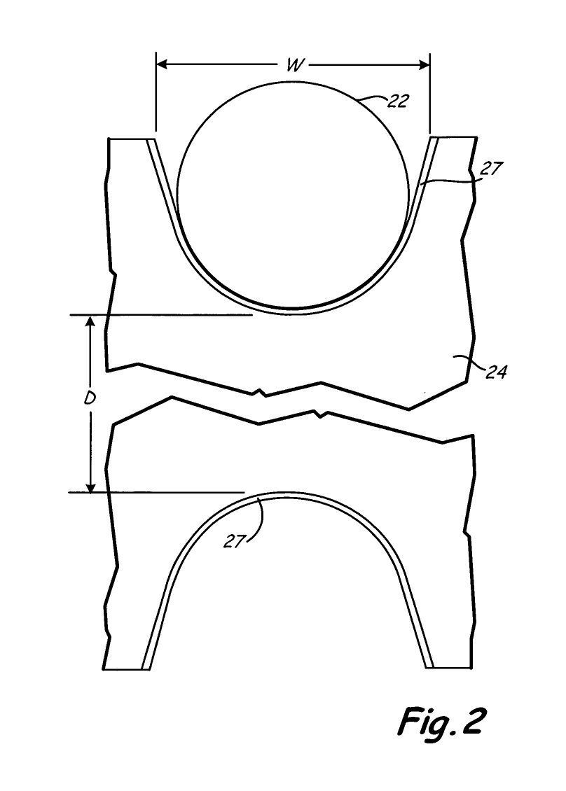

FIG. 2 shows the tension member 22 and the sheave 24 in more detail. Sheaves such as sheave 24 have traditionally been made from cast iron, and have had adequate wear and resistance to friction losses in smaller system. The tension member shown is a single rope. Other tension members are formed from a plurality of twisted strands, each made up of metallic wires. Still other tension members are also contemplated, since elevator systems include a variety of ropes and other friction elements that contact sheaves. All that is necessary is that the tension member frictionally engage the sheave 24. It should be noted that the sheave 24 is shown as separate parts because the minimum ratio of the diameter of a sheave and a rope is 40:1.

Sheave 24 is shown with a coating 27 that has been applied to it in the region where the tension member 22 engages the sheave 24. The coating, 27, is shown larger than in actual practice to illustrate its relationship to the sheave 24 and tension member 22. The sheave 24 has a predetermined width and diameter prior to having coating 27 applied to it, and after coating, as shown in FIG. 2, the width W and diameter D are, within tolerances, the same as the specifications for a pre-coated sheave.

The wear coefficient of a sheave is essentially a measurement of the wear rate of the surface. In evaluating wear on surfaces, the volume of wear that is measured (V)mm³ is equal to the wear coefficient (K) mm²/n times the applied load (P) N (Newtons) times the sliding distance (D) mm. As a formula, this is V=K(PD), where V, K, P and D are defined as above.

Coating 27 may be any coating that reduces the wear coefficient of the region of sheave 24 in contact with the tension member 22. Cast iron Grade 40, which is a conventional material for sheave construction, has a wear coefficient K of about 1.03×10⁻⁹ mm²/N. Preferred are wear coefficients of less than about 2.0×10⁻¹⁰ mm²/N and more preferred are wear coefficients of less than about 1.0×10⁻¹⁰ mm²/N. This translates into a wear coefficient that is about 20% of the wear coefficient of the uncoated sheave 24 (i.e., an 80% reduction in wear coefficient). Preferred is a reduction of the wear coefficient by about 15%, and most preferred is a reduction in wear coefficient by about 10% from the wear coefficient of an uncoated sheave. The range of 80% to 90% reduction has been found to significantly improve the life of the sheave and of the ropes or other friction elements that are in contact with such a coating. The coating thickness will vary depending on the type of coating applied, the forces the friction element presents to the sheave, and the size of the sheave and friction element, as well as other factors.

A wide variety of coatings may be used with the present invention. Examples, by way of example and not as a limitation, include pure metal powders include aluminum, cobalt, copper, iron, nickel, molybdenum, and titanium. Metal alloy powders include alloys of two or more elements selected from aluminum, cobalt, copper, nickel, molybdenum, silicon and iron. Metal carbide powders include chromium carbide and tungsten carbide. Ceramic oxide powders include aluminum oxide, chromium oxide, titanium oxide, and zirconium oxide. Metal wires include aluminum, cobalt, copper, iron, nickel, titanium and alloy wires of two or more elements selected from aluminum, cobalt, copper, nickel, molybdenum, silicon and iron, as well as wires containing chromium carbide and tungsten carbide.

Coatings selected from the group consisting of cobalt alloys having a chromium component, molybdenum, cobalt phosphorus and nickel tungsten alloys. An exemplary cobalt alloy has a trade designation of Stellite 6, and has a composition by wt. % of about 27% chromium, 4% tungsten, 3% iron and 3% nickel, and 1% silicon and 1% carbon. Molybdenum is pure and not an alloy. Cobalt phosphorous is a cobalt alloy with by wt. % 4% to 6% phosphorous. Nickel tungsten alloys have by wt. % about 65% nickel and 35% tungsten.

The coatings may be applied in a variety of ways. All that is necessary is to apply the material, whether a metal or an alloy or other material, to the intended surface to permit the material to harden and bond to the sheave surface. High velocity oxygen fuel spray, plasma spray, cold spray, arc-wire, laser cladding and electroplating methods are all preferred. Once the coating has been applied, it can be fused by application of additional heat, or that step can be omitted. The most effective method for applying the coating, of course, requires that the source of energy be sufficiently portable to be brought into the machine room 26 so that the sheave 24 can be coated in place, without requiring it to be removed or dismantled from motor 20. Thermal spray processes such as flame spray, cold spray, arc-wire and plasma spray are preferred.

When it is time to repair a sheave, the repair crew enters the machine room 26 and fixes the elevator car 14 and counterweight 16 in place so they do not move. Rope or tension member 22 is removed by rotation of the motor drive unit 20. The surface of traction sheave 24 (under coating 27 in FIG. 2) is cleaned as necessary, using mechanical and chemical means so that the surface is smooth. It may also be desirable to machine the surface of sheave 24 so that it is smooth, thus insuring that the coating 27 will have a uniform surface to attach to. If the sheave being repair is the traction sheave, then the present invention can use the machine 20 to turn the sheave during this machining process. If the sheave being repaired is in the traction sheave, then the present invention can use the machine 20 to turn the sheave during this machining process

The desired coating is then applied using equipment that can be brought into the machine room. Thermal spray processes such as flame spray, arc-wire and plasma can be scaled down or modified to fit in the machine room. Cold spray may also be used. Microplasma spray systems, cold spray systems, spray welders and brush plating have all been found to be sized appropriately to be used in a machine room. A uniform coating thickness is best achieved by rotating the sheave using the motor 20 while applying the coating using any of the methods described herein.

The coating can range in thickness from about 0.1 mm to 1.25 mm, with a thinner coating being less expensive in material cost and processing cost. More preferred is a range of about 0.125 mm to about 1.0 mm, and most preferred is from about 0.15 mm to about 0.75 mm. All that is necessary is to have a sufficient thickness to present a wear resistant surface with a wear coefficient K (mm² N) of less than about 2.0×10⁻¹⁰ mm²N as noted above.

As noted in FIG. 2, there is a diameter D and width W that indicate the dimensions of the sheave, with the coating 27 on sheave 24. These dimensions are the actual specified dimensions of a new sheave. In many cases sheaves wear and the dimensions change because of the wear they experience. Most often the diameter decreases because cast iron has been removed by friction from the rope or other friction element. As part of the repair of the sheave, the surfaces are to be cleaned and made smooth before the coating is applied. After application of the coating using motor 20 to turn sheave 24 during coating, the dimensions are to be checked against specifications and adjusted when necessary. Single point turning can also be accomplished using the motor 20 to turn sheave 24, similar to a lathe process.

A number of materials were evaluated as coatings for sheaves in accordance with the present invention. The wear coefficient K mm²=V mm³/(P N×D mm) is determined by measuring the volume V in cubic millimeters of wear debris from the sheave surface as it is subjected to a load in Newtons (N) over a distance in millimeters. Tests were run on various coatings using a first load of 444 Newtons over a span of 8.9 mm over a single day of testing. Other tests at 222 Newtons and 666 Newtons were made on selected coatings. Presented below in Table I are the results of some of tests showing a significant improvement in the wear coefficient K in mm²n as noted above.

TABLE I

| | WEAR | ROPE WEAR |
|---|---|---|
| | COEFFICIENT | COEFFICIENT |
| | K mm² N = Vmm³/ | K mm² N = Vmm³/ |
| SHEAVE COATING | (P n × D mm) | (P n × D mm) |
| Cast Iron Grade 40 | 1.03 × 10⁻⁹ | 1.37 × 10⁻⁹ |
| (control) | | |
| Cobalt Chrome alloy | 1.87 × 10⁻¹⁰ | 5.01 × 10⁻¹⁰ |
| Molybdenum | 1.37 × 10⁻¹⁰ | 4.73 × 10⁻¹⁰ |
| Cobalt Phosphorous | 0.81 × 10⁻¹⁰ | 5.71 × 10⁻¹⁰ |
| Nickel-Tungsten | 1.19 × 10⁻¹⁰ | 1.33 × 10⁻¹⁰ |

As can be seen from the data in Table I, the four coatings that were tested reduced the coefficient of wear of the sheave significantly and also resulted in improved wear on the ropes when compared to the same rope used on an uncoated sheave. In some cases the sheave wear coefficient improved to a value less than 18.2% to as low as 6.25% of the control wear coefficient. The rope wear coefficient improvement ranged from 41.7% to 9.7% of the wear coefficient compared to the control.

Although the present invention has been described with reference to preferred embodiments, workers skilled in the art will recognize that changes may be made in form and detail without departing from the spirit and scope of the invention.

1. A method of repairing a sheave in an elevator system, the method comprising:
restoring the sheave to a desired condition; and
depositing a coating on a surface of the sheave to produce a coated sheave having a wear coefficient of the surface of the sheave to a wear coefficient less than about 2.0×10⁻¹⁰ mm²N.

2. The method of claim 1, wherein the elevator system includes at least one friction member associated with the sheave, and further comprising the step of moving the at least one friction member associated with the sheave to permit access to the surface.

3. The method of claim 1, wherein the restoring step includes cleaning or machining the sheave.

4. The method of claim 2, wherein the elevator system includes a machine, and the machine is used to rotate the sheave during movement of the rope, depositing the coating and the further step of adjusting the thickness of the coated sheave to a predetermined value if necessary.

5. The method of claim 1, wherein the wear coefficient of the coated sheave is less than 1.0×10¹⁰ mm²N.

6. The method of claim 5, wherein the wear coefficient of the coated sheave is about 10% of the wear coefficient of a sheave of the same material without a coating.

7. The method of claim 6, wherein the coating is selected from the group consisting of cobalt alloys having a chromium component, molybdenum, cobalt phosphorus and nickel tungsten alloys.

8. The method of claim 1, wherein the coating is applied to the sheave by a process selected from high velocity oxygen fuel, plasma spray, cold spray, arc-wire, laser cladding and electroplating methods.

9. The method of claim 6, wherein the coating is fused after being applied.

10. The method of claim 1, wherein the restoring step includes machining the sheave to less than a specified dimension prior to depositing the coating, and wherein the coating restores the sheave to the specified dimension.

11. The method of claim 10, wherein the coating thickness is adjusted by selective removal of the coating by single point turning.

12. The method of claim 1, where the coating thickness ranges from about 0.1 mm to about 1.25 mm.

13. A method of preparing a sheave device for use in an elevator system having at least one friction element and sheave combination, comprising the steps of:
exposing a sheave by moving the at least one friction element; and
forming a coating on the sheave having a wear coefficient less than about 2.0×10⁻¹⁰ mm²N to produce a coated sheave without removing the sheave from the elevator system.

14. The method of claim 13, wherein the sheave is located in an elevator system having a car, a counterweight, and a hoist motor to rotate the sheave during depositing the coating.

15. The method of claim 14, wherein the motor is used to rotate the sheave to adjust the thickness of the coated sheave to a specified dimension, the thickness of the coating ranging from about 0.1 mm to about 1.25 mm.

16. The method of claim 13, wherein the wear coefficient on the sheave is less than about 1.0×10⁻¹⁰ mm²N.

17. The method of claim 15, wherein the wear coefficient on the coated sheave is about 10% of the wear coefficient of the sheave without a coating.

18. The method of claim 13, wherein the coating is selected from the group consisting of cobalt alloys having a chromium component, molybdenum, cobalt phosphorus and nickel tungsten alloys.

19. The method of claim 13, wherein the coating is applied to the sheave by a process selected from high velocity oxygen fuel, plasma spray, cold spray, arc-wire, laser cladding and electroplating methods.

20. The method of claim 19, wherein the coating is fused after being applied.
